(19) United States
(12) Patent Application Publication
(10) Pub. No.: US 2008/0061851 A1
(43) Pub. Date: Mar. 13, 2008

(54) DELAY LOCKED LOOP CIRCUIT CAPABLE OF REDUCING BANG-BANG JITTER

(75) Inventor: Young-Jin JEON, Daejeon (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 11/852,884

(22) Filed: Sep. 10, 2007

(30) Foreign Application Priority Data
Sep. 13, 2006 (KR) 2006-0088691

(51) Int. Cl. H03L 7/089

(52) U.S. Cl. 327/158

(57) ABSTRACT

A delay locked loop circuit is provided that can reduce bang-bang jitter in the circuit. In one embodiment, the delay locked loop circuit includes a phase detector, a first detection unit, a second detection unit, a delay unit, and a variable delay circuit. In the delay locked loop circuit, the variable delay circuit may be disabled or temporarily deactivated when two or more similar control signals are received to reduce bang-bang jitter in the circuit.

### CROSS-REFERENCE TO RELATED PATENT APPLICATION

This application claims the benefit of Korean Patent Application No. 10-2006-0088691, filed on Sep. 13, 2006, in the Korean Intellectual Property Office, the disclosure of which is incorporated herein in its entirety by reference.

### BACKGROUND

1. Field of the Invention

The present invention relates to an electronic circuit, and more particularly, to a delay locked loop circuit which can reduce bang-bang jitter.

2. Description of the Related Art

Generally, synchronous semiconductor memory devices such as synchronous dynamic random access memories (SDRAMs) use an internal clock signal synchronized with an external clock signal to write or read data. The internal clock signal is generated using a delay locked loop (DLL) circuit.

FIG. 1 is a block diagram of a conventional delay locked loop circuit 100.

Referring to FIG. 1, the delay locked loop circuit 100 includes a clock buffer 105, a variable delay circuit 110, a phase detector 125, a delay controller 130, and a replica clock buffer 135.

The clock buffer 105 generates a reference clock signal (RCK) by buffering an external clock signal (ECK).

The variable delay circuit 110 delays the reference clock signal (RCK) in order for a phase of the reference clock signal (RCK) and a phase of a feedback clock signal (FCK) to be synchronized (coincide) with each other. In other words, the variable delay circuit 110 delays the reference clock signal (RCK) and generates an output clock signal (DCK) having a phase synchronized with a phase of the external clock signal (ECK), in response to a control signal (CNT). The output clock signal (DCK), which is an output of the delay locked loop circuit 100, can be provided to a data output buffer of a synchronous semiconductor memory device.

The variable delay circuit 110 includes a coarse lock unit 115 and a fine lock unit 120. The coarse lock unit 115 delays the reference clock signal (RCK) by a first delay time in response to the control signal (CNT). The fine lock unit 120 delays the output signal of the coarse lock unit 115 by a second delay time to generate the output clock signal (DCK), in response to the control signal (CNT). The first delay time is longer than the second delay time. That is, the coarse lock unit 115 delays the reference clock signal (RCK) by a relatively large delay amount until a phase difference between the reference clock signal (RCK) and the feedback clock signal (FCK) approaches a predetermined offset range. After a coarse lock operation is performed by the coarse lock unit 115, the fine lock unit 120 delays the reference clock signal (RCK) by a relatively small delay amount to synchronize the phase of the reference clock signal (RCK) with the phase of the feedback clock signal (FCK).

The replica clock buffer 135 delays the output clock signal (DCK) by a delay time substantially similar to the time that the clock signal is delayed by in the clock buffer 105 to generate the feedback clock signal (FCK). In other words, the replica clock buffer 135 replicates or copies the delay time that the clock signal is delayed in the clock buffer 105.

The phase detector 125 compares the phase of the reference clock signal (RCK) and the phase of the feedback clock signal (FCK) to output an up signal (UP) or a down signal (DN). The up signal (UP) is generated when the phase of the reference clock signal (RCK) lags behind the phase of the feedback clock signal (FCK) and indicates the need for an increase of the delay time of the clock signal in the variable delay circuit 110. On the other hand, the down signal (DN) is generated when the phase of the reference clock signal (RCK) leads the phase of the feedback clock signal (FCK) and indicates the need for a decrease of the delay time of the clock signal in the variable delay circuit 110.

The delay controller 130 generates the control signal (CNT) which controls the phase of the reference clock signal (RCK) and the phase of the feedback clock signal (FCK) so that they are synchronized, in response to the up signal (UP) or the down signal (DN). The delay controller 130 may include a charge pump circuit and a low pass filter.

FIG. 2 is a timing diagram illustrating bang-bang jitter generated in the output clock signal (DCK) of FIG. 1. More specifically, FIG. 2 illustrates a timing diagram after a fine lock is performed between the reference clock signal (RCK) and the feedback clock signal (FCK) by the fine lock unit 120 of FIG. 1. Before the fine lock is performed, the up signal (UP) or the down signal (DN) may be repeatedly generated.

Referring to FIGS. 1 and 2, even after the fine lock is performed between the reference clock signal (RCK) and the feedback clock signal (FCK), the phase of the reference clock signal (RCK) and the phase of the feedback clock signal (FCK) that are inputted in the phase detector 125 are not often synchronized due to changes of process, voltage, and temperature, or noise which may be generated in the delay locked loop circuit 100. Thus, the phase detector 125 may continuously operate in an attempt to synchronize the phases of the reference clock signal (RCK) and the feedback clock signal (FCK). As a result, the up signal (UP) is repeatedly generated by being synchronized with a predetermined clock cycle of the reference clock signal (RCK) and the down signal (DN) is repeatedly generated by being synchronized with a next cycle of the clock cycle of the reference clock signal (RCK) as illustrated in FIG. 2. That is, even after the fine lock is performed, the up signal (UP) and the down signal (DN) are alternately generated. Subsequently, the bang-bang jitter phenomenon may be generated in the output clock signal (DCK) of the delay locked loop circuit 100 due to the up signal (UP) and the down signal (DN) being alternately generated. Such bang-bang jitter of the output clock signal (DCK) may generate a jitter in output data of a corresponding synchronous semiconductor memory device. The phase difference between the reference clock signal (RCK) and the feedback clock signal (FCK) while the bang-bang jitter is generated corresponds to the delay time of the clock signal in the fine lock unit 120.

### SUMMARY

The present invention provides a delay locked loop circuit which can reduce bang-bang jitter.

According to an embodiment of the present invention, a delay locked loop circuit includes a phase detector, a first detection unit, a second detection unit, a delay unit, and a variable delay circuit. The phase detector outputs a first up signal when the phase of a reference clock signal lags behind the phase of a feedback clock signal. The phase detector alternatively outputs a first down signal when the phase of the reference clock signal leads the phase of the feedback clock signal. The first detection unit generates a second up signal activated when two or more of the first up signals are detected. The first detection unit also generates a second down signal activated when two or more of the first down signals are detected. The second detection unit detects whether the first up signal and the first down signal are outputted alternately and generates a detection signal that is activated when the first up signal is outputted alternately. The delay unit delays the feedback clock signal so that it is synchronized with the reference clock signal in response to the activated detection signal. The variable delay circuit, which includes a coarse lock unit and a fine lock unit, delays the reference clock signal to be synchronized with the feedback clock signal in response to a control signal generated based on the activated second up signal or the activated second down signal. In the above delay locked loop circuit the first up signal outputted alternately is generated after a fine lock is performed by the fine lock unit, and the variable delay circuit is disabled in response to the second up signal or the second down signal, where it is deactivated after the fine lock is performed.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a conventional delay locked loop circuit;

FIG. 2 is a timing diagram illustrating a bang-bang jitter generated in an output clock signal (DCK) of FIG. 1;

FIG. 3 is a diagram of a delay locked loop circuit according to an embodiment of the present invention;

FIG. 4 is a diagram of a first detection unit shown in FIG. 3 according to an embodiment of the present invention; and

FIG. 5 is a timing diagram illustrating a reduction in the bang-bang jitter in an output clock signal (DCK) of the delay locked loop circuit shown in FIG. 3.

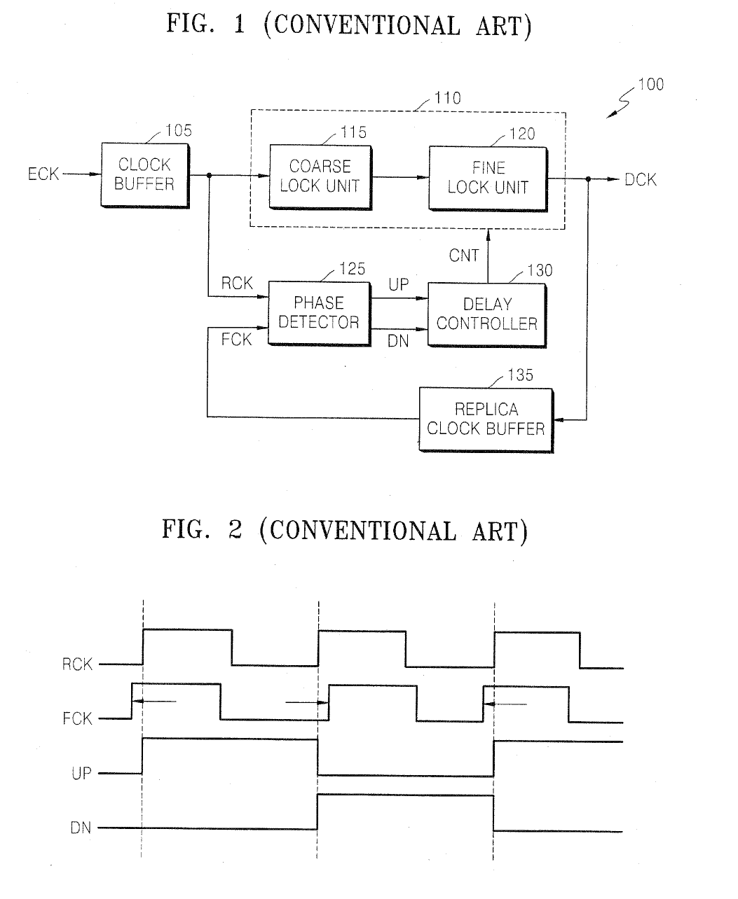

### DETAILED DESCRIPTION

Hereinafter, the present invention will be described more fully with reference to the accompanying drawings, in which exemplary embodiments of the invention are shown. In the drawings, like reference numerals denote like elements.

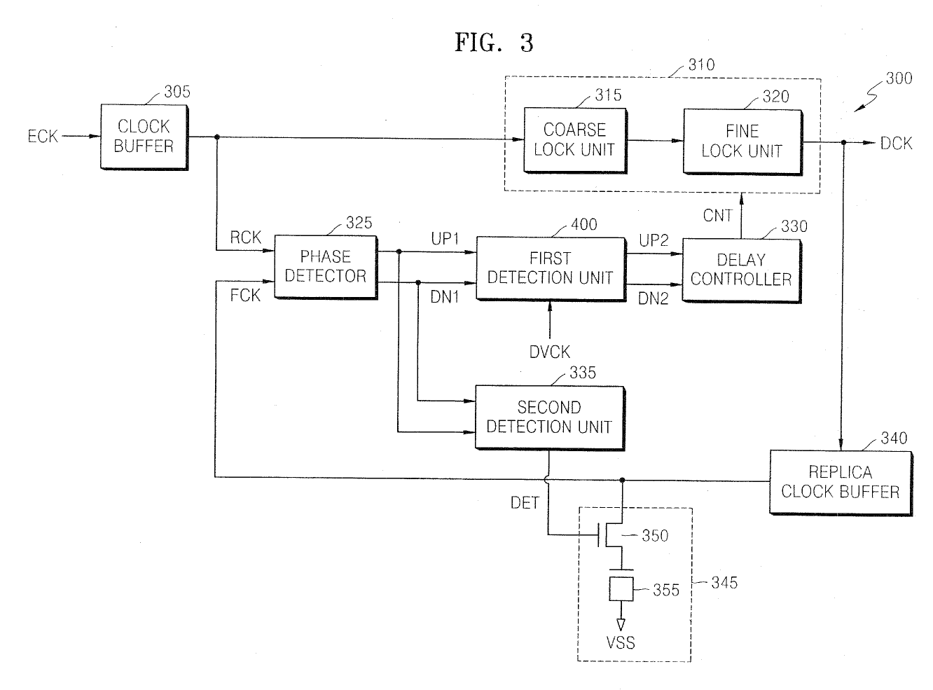

FIG. 3 is a diagram of a delay locked loop circuit 300 according to an embodiment of the present invention.

Referring to FIG. 3, the delay locked loop circuit 300 includes a clock buffer 305, a variable delay circuit 310, a phase detector 325, a first detection unit 400, a delay controller 330, a second detection unit 335, a replica clock buffer 340, and a delay unit 345.

The clock buffer 305 buffers an external clock signal (ECK) to generate a reference clock signal (RCK).

The variable delay circuit 310 delays the reference clock signal (RCK) in order for a phase of the reference clock signal (RCK) and a phase of a feedback clock signal (FCK) to be synchronized. In other words, the variable delay circuit 310 delays the reference clock signal (RCK) and generates an output clock signal (DCK), having a phase synchronized with a phase of the external clock signal (ECK), in response to a control signal (CNT). The output clock signal (DCK), which is an output of the delay locked loop circuit 300, can be provided to a data output buffer of a synchronous semiconductor memory device.

The variable delay circuit 310 includes a coarse lock unit 315 and a fine lock unit 320. The coarse lock unit 315 delays the reference clock signal (RCK) by a first delay time in response to the control signal (CNT). The fine lock unit 320 delays the output signal of the coarse lock unit 315 by a second delay time to generate the output clock signal (DCK) in response to the control signal (CNT). The first delay time is longer than the second delay time. That is, the coarse lock unit 315 delays the reference clock signal (RCK) by a relatively large delay amount until the phase difference between the reference clock signal (RCK) and the feedback clock signal (FCK) approaches a predetermined offset range. After a coarse lock operation is performed by the coarse lock unit 315, the fine lock unit 320 delays the reference clock signal (RCK) by a relatively small delay amount to synchronize the phase of the reference clock signal (RCK) with the phase of the feedback clock signal (FCK).

The replica clock buffer 340 delays the output clock signal (DCK) by substantially the same delay time that the clock signal is delayed by in the clock buffer 305 to generate the feedback clock signal (FCK). In other words, the replica clock buffer 340 replicates the delay time that the clock signal is delayed by in the clock buffer 305.

The phase detector 325 compares the phase of the reference clock signal (RCK) and the phase of the feedback clock signal (FCK) to output a first up signal (UP1) or a first down signal (DN1). The first up signal (UP1) is generated when the phase of the reference clock signal (RCK) lags behind the phase of the feedback clock signal (FCK) and indicates the need for an increase of the delay time of the clock signal in the variable delay circuit 310. In addition, the first down signal (DN1) is generated when the phase of the reference clock signal (RCK) leads the phase of the feedback clock signal (FCK) and indicates the need for a decrease of the delay time of the clock signal in the variable delay circuit 310.

The first detection unit 400 detects the number of the first up signal (UP1) outputted from the phase detector 325 and either generates a second up signal (UP2) activated with high level when the number of the first up signal (UP1) detected is 2 or more, or generates a second up signal (UP2) deactivated with low level when the number of the first up signal (UP1) detected is less than 2, in response to a division clock signal (DVCK).

In other words, as mentioned above, when the number of the first up signal (UP1) outputted from the phase detector 325 is 2 or more before a fine lock is performed between the reference clock signal (RCK) and the feedback clock signal (FCK) by the fine lock unit 320, the first detection unit 400 generates the second up signal (UP2) with a high level. In addition, as mentioned above, when the first up signal (UP1) and the first down signal (DN1) are alternately outputted from the phase detector 325 after the fine lock is performed, the first detection unit 400 generates the second up signal (UP2) with a low level. The second up signal (UP2) with a high level enables the delay controller 330 and directs the delay controller 330 to control the delay time of the clock signal in the variable delay circuit 310 so that the delay time increases. The second up signal (UP2) with a low level disables the delay controller 330 so that the variable delay circuit 310 is not operated.

In addition, the first detection unit 400 detects the number of the first down signal (DN1) outputted from the phase detector 325 and either generates a second down signal (DN2) activated with high level when the number of the first down signal (DN1) detected is 2 or more, or generates a second down signal (DN2) deactivated with low level when the number of the first down signal (DN2) detected is less than 2, in response to a division clock signal (DVCK).

In other words, as mentioned above, when the number of the first down signal (DN1) outputted from the phase detector 325 is 2 or more before the fine lock is performed between the reference clock signal (RCK) and the feedback clock signal (FCK) by the fine lock unit 320, the first detection unit 400 generates the second down signal (DN2) with a high level. In addition, as mentioned above, when the first up signal (UP1) and the first down signal (DN1) are alternately outputted from the phase detector 325 after the fine lock is performed, the first detection unit 400 generates the second down signal (DN2) with a low level. The second down signal (DN2) with a high level enables the delay controller 330 and directs the delay controller 330 to control the delay time of the clock signal in the variable delay circuit 310 so that the delay time decreases. The second down signal (DN2) with low level disables the delay controller 330 so that the variable delay circuit 310 is not operated.

Therefore, since the variable delay circuit 310 is not operated by the first detection unit 400 after the fine lock is performed, the bang-bang jitter can be reduced in the output clock signal (DCK).

A division ratio of the division clock signal (DVCK) may be determined by considering a lock time of the delay locked loop circuit 300. The division clock signal (DVCK) may be, for example, a 12 division clock signal of the reference clock signal (RCK).

The delay controller 330 generates the control signal (CNT), which controls the phase of the reference clock signal (RCK) and the phase of the feedback clock signal (FCK) to be synchronized, in response to the second up signal (UP2) or the second down signal (DN2). The delay controller 330 may include a charge pump circuit and/or a low pass filter.

The second detection unit 335 receives the first up signal (UP1) and the first down signal (DN1) outputted from the phase detector 325 and detects whether the received first up signal (UP1) and first down signal (DN1) are outputted alternately, while the first detection unit 400 is operated. The alternate output of the first up signal (UP1) and first down signal (DN1) that is of particular concern from the second detection unit 335 may be after the fine lock is performed by the fine lock unit 320.

The second detection unit 335 generates a detection signal (DET) activated with high level when the first up signal (UP1) outputted alternately is detected and generates a detection signal (DET) deactivated with low level when the first up signal (UP1) outputted alternately is not detected. The detection signal (DET) with low level disables the delay unit 345.

The detection signal (DET) at high level enables the delay unit 345 to delay the feedback clock signal (FCK) by a delay time of the clock signal in the fine lock unit 320. The delay time of the clock signal in the fine lock unit 320 corresponds to the phase difference between the reference clock signal (RCK) and the feedback clock signal (FCK) when the bang-bang jitter is generated in the output clock signal (DCK). Due to the delay of the feedback clock signal (FCK), the phase of the reference clock signal (RCK) and the phase of the feedback clock signal (FCK) can be synchronized. As a result, the phase detector 325 is disabled and thus the first up signal (UP1) or the first down signal (DN1) are not generated. Therefore, the bang-bang jitter can be reduced in the output clock signal (DCK).

The delay unit 345 delays the feedback clock signal (FCK) by the delay time of the clock signal in the fine lock unit 320, in response to the detection signal (DET) with high level. The delay unit 345 includes a NMOS capacitor 355 in which one end thereof is connected to ground voltage (VSS) and a NMOS transistor 350 which is turned on by the detection signal (DET) with high level and connects the other end of the NMOS capacitor 355 with a signal line transmitting the feedback clock signal (FCK). The delay unit 345 delays the feedback clock signal (FCK) using an ON resistance of the NMOS transistor 350 and a capacitance of the NMOS capacitor 355.

As described above, the delay locked loop circuit 300 according to the present invention can disable the variable delay circuit 310 and the phase detector 325 using the first detection unit 400 and the second detection unit 335 operated in response to the first up signal (UP1) and the first down signal (DN1), wherein the first up signal (UP1) and the first down signal (DN1) are generated after the fine lock is performed by the fine lock unit 320, and thus the bang-bang jitter can be reduced in the output clock signal (DCK).

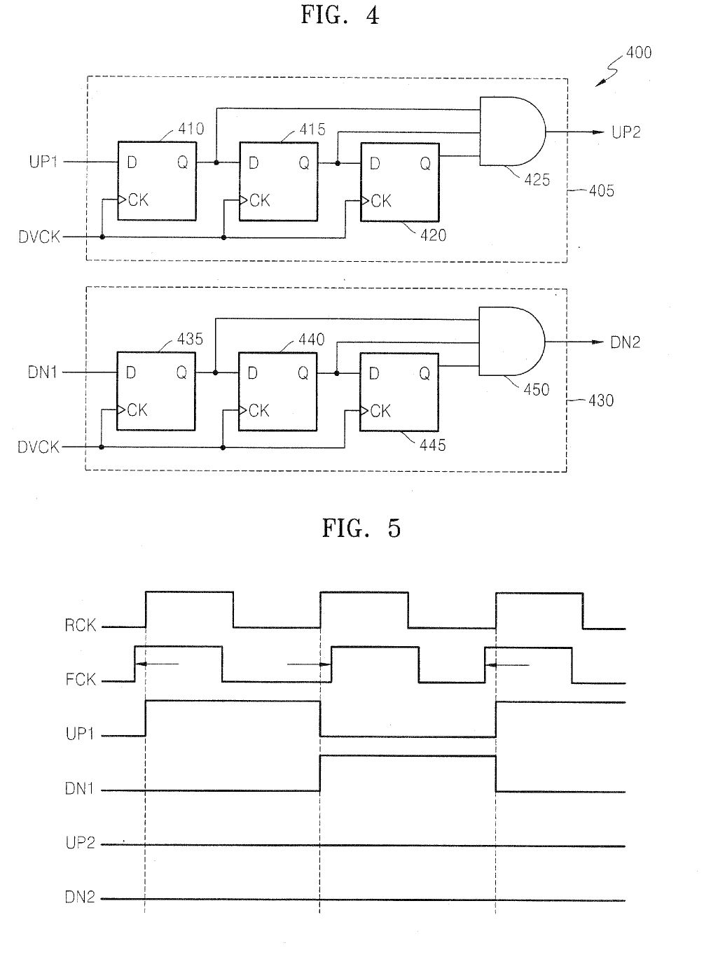

FIG. 4 is a diagram of the first detection unit 400 of FIG. 3 according to an embodiment of the present invention.

Referring to FIG. 4, in the first detection unit 400, noises in the number of the first up signal (UP1) or the number of the first down signal (DN1) successively outputted from the phase detector 325 are considered. In other words, in the first detection unit 400, when 3 first up signals (UP1) are successively outputted, the second up signal (UP2) is activated, and when 3 first down signals (DN1) are successively outputted, the second down signal (DN2) is activated. In addition, the first detection unit 400 includes an up signal generation unit 405 and a down signal generation unit 430.

The up signal generation unit 405 detects the number of the first up signal (UP1) inputted in response to the division clock signal (DVCK), generates the second up signal (UP2) activated with a high level when the number of the detected first up signal (UP1) is 3, and generates the second up signal (UP2) deactivated with low level when the number of the detected first up signal (UP1) is less than 3.

The up signal generation unit 405 includes a first D flip-flop 410, a second D flip-flop 415, a third D flip-flop 420, and an AND gate 425. When there is no noise in the number of the first up signal (UP1) inputted, the up signal generation unit 405 does not include the third D flip-flop 420 and only output signals of the first and second D flip-flops 410 and 415 are inputted in the AND gate 425.

The first D flip-flop 410 samples the first up signal (UP1) in response to the division clock signal (DVCK), the second D flip-flop 415 samples the output signal of the first D flip-flop 410 in response to the division clock signal (DVCK), and the third D flip-flop 420 samples the output signal of the second D flip-flop 415 in response to the division clock signal (DVCK).

The AND gate 425 performs an AND operation with respect to the output signals of the first D flip-flop 410, the second D flip-flop 415, and the third D flip-flop 420 to generate the second up signal (UP2).

The down signal generation unit 430 detects the number of the first down signal (DN1) inputted in response to the division clock signal (DVCK), generates the second down signal (UP2) activated with high level when the number of the detected first down signal (DN1) is 3, and generates the second down signal (DN2) deactivated with low level when the number of the detected first down signal (DN1) is less than 3.

The down signal generation unit 430 includes a first D flip-flop 435, a second D flip-flop 440, a third D flip-flop 445, and an AND gate 450. When there is no noise in the number of the first down signal (DN1) inputted, the down signal generation unit 430 does not include the third D flip-flop 445 and only output signals of the first and second D flip-flops 435 and 440 are inputted in the AND gate 450.

The first D flip-flop 435 samples the first down signal (DN1) in response to the division clock signal (DVCK), the second D flip-flop 440 samples the output signal of the first D flip-flop 435 in response to the division clock signal (DVCK), and the third D flip-flop 445 samples the output signal of the second D flip-flop 440.

The AND gate 450 performs an AND operation with respect to the output signals of the first D flip-flop 435, the second D flip-flop 440, and the third D flip-flop 445 to generate the second down signal (DN2).

FIG. 5 is a timing diagram illustrating when the bang-bang jitter is reduced in the output clock signal (DCK) of FIG. 3.

Referring to FIGS. 3 and 5, after the fine lock is performed between the reference clock signal (RCK) and the feedback clock signal (FCK) by the fine lock unit 320 corresponding to when the bang-bang jitter is generated in the output clock signal (DCK), both second up signal (UP2) and second down signal (DN2) are deactivated to have a low level and thus the delay controller 330 is disabled. As a result, since the variable delay circuit 310 is not operated after the fine lock is performed, the bang-bang jitter can be reduced in the output clock signal (DCK).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A delay locked loop circuit comprising:
a phase detector configured to output a first up signal when a phase of a reference clock signal lags behind a phase of a feedback clock signal and output a first down signal when the phase of the reference clock signal leads the phase of the feedback clock signal;
a first detection unit configured to generate a second up signal that is activated when the number of the first up signal detected is two or more and generate a second down signal that is activated when the number of the first down signal detected is two or more;
a second detection unit configured to generate a detection signal when the first up signal and the first down signal are outputted alternately;
a delay unit configured to delay the feedback clock signal to be synchronized with the reference clock signal in response to the activated detection signal; and
a variable delay circuit including a coarse lock unit and a fine lock unit, wherein the coarse lock unit and the fine lock unit are configured to delay the reference clock signal to be synchronized with the feedback clock signal in response to a control signal generated as a function of the activated second up signal or the activated second down signal,
wherein the variable delay circuit is disabled in response to a deactivated second up signal or a deactivated second down signal after a fine lock is performed.

2. The delay locked loop circuit of claim 1, further comprising a delay controller configured to generate the control signal.

3. The delay locked loop circuit of claim 1, wherein the first detection unit is configured to generate the deactivated second up signal when the number of the first up signal is less than two and generate the deactivated second down signal when the number of the first down signal is less than two.

4. The delay locked loop circuit of claim 3, wherein the first detection unit comprises:
an up signal generation unit configured to detect the number of the first up signal in response to a division clock signal of the reference clock signal and generate the second up signal that is activated when the detected number of the first up signal is three; and
a down signal generation unit configured to detect the number of the first down signal in response to the division clock signal and generate the second down signal that is activated when the detected number of the first down signal is three.

5. The delay locked loop circuit of claim 4, wherein the up signal generation unit comprises:
a first D flip-flop configured to sample the first up signal in response to the division clock signal;
a second D flip-flop configured to sample the output signal of the first D flip-flop in response to the division clock signal;
a third D flip-flop configured to sample the output signal of the second D flip-flop in response to the division clock signal; and
an AND gate configured to perform an AND operation with respect to the output signals of the first D flip-flop, the second D flip-flop, and the third D flip-flop to generate the second up signal.

6. The delay locked loop circuit of claim 4, wherein the down signal generation unit comprises:
a first D flip-flop configured to sample the first down signal in response to the division clock signal;
a second D flip-flop configured to sample the output signal of the first D flip-flop in response to the division clock signal;
a third D flip-flop configured to sample the output signal of the second D flip-flop in response to the division clock signal; and
an AND gate configured to perform an AND operation with respect to the output signals of the first D flip-flop, the second D flip-flop, and the third D flip-flop to generate the second down signal.

7. The delay locked loop circuit of claim 1, wherein the delay unit is configured to delay the feedback clock signal by the delay time that the clock signal is delayed by in the fine lock unit.

8. The delay locked loop circuit of claim 7, wherein the delay unit comprises:
a NMOS capacitor having one end thereof connected to ground voltage; and
a NMOS transistor configured to be turned on by the activated detection signal and connecting a second end of the NMOS capacitor to a signal line transmitting the feedback clock signal.

9. The delay locked loop circuit of claim 1, further comprising:
a clock buffer configured to buffer an external clock signal to generate the reference clock signal; and
a replica clock buffer configured to delay an output clock signal that is an output of the variable delay circuit by a delay time that the clock signal is delayed by in the clock buffer to generate the feedback clock signal.

10. A method of preventing bang-bang jitter in a delay locked loop circuit, the method comprising:
delaying a reference clock signal to be synchronized with a feedback clock signal in a variable delay circuit including a coarse lock unit and a fine lock unit;
outputting a first up signal when a phase of the reference clock signal lags behind a phase of the feedback clock signal and outputting a first down signal when the phase of the reference clock signal leads the phase of the feedback clock signal; and
generating a second up signal that is activated when the number of the first up signal is two or more and generating a second down signal that is activated when the number of the first down signal is two or more; and
deactivating the variable delay circuit in response to a second up signal that is deactivated after a fine lock is performed by the fine lock unit or in response to a second down signal that is deactivate after the fine lock is performed by the fine lock unit.

11. The method of claim 10, wherein the second up signal and the second down signal are deactivated after the fine lock is performed when the first up signal and first down signal alternate after the fine lock is performed.

12. The method of claim 10, further comprising:
detecting whether the first up signal and the first down signal are alternately outputted;
generating an activated detection signal when the first up signal and first down signal are alternately outputted; and
delaying the feedback clock signal in a delay unit by a delay time of the reference clock signal in the fine lock unit of the variable delay circuit in response to the activated detection signal;
